(19) United States
(12) Patent Application Publication
(10) Pub. No.: US 2024/0400855 A1
(43) Pub. Date: Dec. 5, 2024

(54) THERMOSETTING RESIN COMPOSITION, CURED PRODUCT, AND PRINTED WIRING BOARD

(71) Applicant: TAIYO HOLDINGS CO., LTD., Hiki-gun, Saitama-ken (JP)

(72) Inventors: Satsuki OZAWA, Hiki-gun, Saitama-ken (JP); Kazuya SATO, Hiki-gun, Saitama-ken (JP); Mariko SHIMAMIYA, Hiki-gun, Saitama-ken (JP); Yasuaki ARAI, Hiki-gun, Saitama-ken (JP); Chika TAKAHASHI, Hiki-gun, Saitama-ken (JP)

(73) Assignee: TAIYO HOLDINGS CO., LTD., Hiki-gun, Saitama-ken (JP)

(21) Appl. No.: 18/697,033

(22) PCT Filed: Sep. 29, 2022
(86) PCT No.: PCT/JP2022/036527

§ 371 Date: Mar. 29, 2024

(30) Foreign Application Priority Data
Sep. 30, 2021 (JP) 2021-162336

(51) Int. Cl. C09D 163/00; C08G 59/24; C08G 59/50; H05K 1/03

(52) U.S. Cl. CPC C09D 163/00; C08G 59/245; C08G 59/5073; H05K 1/0373

(57) ABSTRACT

Provided is a thermosetting resin composition whose semi-cured state and fully cured state can be visually distinguished.

The thermosetting resin composition according to the invention is a thermosetting resin composition including a thermosetting resin, a curing agent, and a filler, in which when
an L* value measured using an L*a*b* color system before curing the thermosetting resin composition is defined as L1,
an L* value measured using the L*a*b* color system for a semi-cured product obtained by thermally curing the thermosetting resin composition at 80° C. for 60 minutes is defined as L2, and
an L* value measured using the L*a*b* color system for a fully cured product obtained by further thermally curing the semi-cured product at 150° C. for 60 minutes is defined as L3,
the thermosetting resin composition satisfies the following Formula 1:

$$( L 2 - L 3 ) / ( L 1 - L 3 ) \geq 0.7 . \qquad ( Formula 1 )$$

### BACKGROUND OF THE INVENTION

### Technical Field

The present invention relates to a thermosetting resin composition. More specifically, the present invention relates to a thermosetting resin composition that can be suitably used as a hole-filling material for filling through-holes and recesses such as through-holes in printed wiring boards. In addition, the present invention relates to a cured product obtained by curing the thermosetting resin composition and a printed wiring board formed using the cured product.

### Background Art

For printed wiring boards having a plurality of conductor pattern layers, such as copper-clad laminates, double-sided printed wiring boards, and multilayer printed wiring boards, holes such as via-holes and through-holes plated with a conductor are provided on the inner wall so as to electrically connect a plurality of conductor pattern layers to each other. These holes are generally filled with a hole-filling material such as a thermosetting resin composition in order to protect the inner wall conductor from etching during conductor pattern formation and improve mounting reliability.

A method for filling through-holes in a printed wiring board using a screen printing method will be described. For example, Patent Literature 1 teaches that when filling through-holes with thermosetting resin, to eliminate the problem of large recesses that occur due to curing shrinkage when a hole-filling material is cured by heating or the like, a portion filled with the hole-filling material (rivet portion) that exists above and below the through-holes is created, and then the filled part is flattened by surface polishing. Patent Literature 2 teaches that semi-curing is performed before full curing to prevent voids from forming, even in the case of full curing after filling resin. However, it was difficult to visually distinguish between the semi-cured state and the fully cured state.

Surface polishing is performed on the thermosetting resin composition after semi-curing or after full curing; however, it is necessary to adjust the polishing conditions according to the cured state of the thermosetting resin composition. Therefore, to adjust the polishing conditions according to the cured state, a method for visually distinguishing between the semi-cured state and the fully cured state has been required.

### CITATION LIST

### Patent Literature

Patent Literature 1: Japanese Unexamined Patent Publication No. 2005-175032
Patent Literature 2: Japanese Unexamined Patent Publication No. 2017-133021

### SUMMARY OF THE INVENTION

### Technical Problem

Therefore, an object of the present invention is to provide a thermosetting resin composition whose semi-cured state and fully cured state can be visually distinguished. Another object of the present invention is to provide a cured product formed using the thermosetting resin composition and a printed wiring board formed using the cured product.

### Solution to Problem

The present invention provides the following thermosetting resin composition to achieve the objects.

[1] The thermosetting resin composition according to the present invention is a thermosetting resin composition comprising a thermosetting resin, a curing agent, and a filler, wherein when
an L* value measured using an L*a*b* color system before curing the thermosetting resin composition is defined as L1,
an L* value measured using the L*a*b* color system for a semi-cured product obtained by thermally curing the thermosetting resin composition at 80° C. for 60 minutes is defined as L2, and
an L* value measured using the L*a*b* color system for a fully cured product obtained by further thermally curing the semi-cured product at 150° C. for 60 minutes is defined as L3, the thermosetting resin composition satisfies the following Formula 1:

$$( L 2 - L 3 ) / ( L 1 - L 3 ) \geq 0.7 . \qquad ( Formula 1 )$$

[2] The thermosetting resin composition according to [1], wherein L1, L2, and L3 satisfy the following Formula 2:

$$( L 2 - L 3 ) / ( L 1 - L 3 ) \geq 0.9 . \qquad ( Formula 2 )$$

[3] The thermosetting resin composition according to [1] or [2], wherein the thermosetting resin is an epoxy resin.

[4] The thermosetting resin composition according to any one of [1] to [3], wherein the curing agent is an imidazole.

[5] The thermosetting resin composition according to any one of [1] to [4], wherein a content of the curing agent is from 3 parts by mass or more and 20 parts by mass or less with respect to 100 parts by mass of the thermosetting resin.

[6] The thermosetting resin composition according to any one of [1] to [5], wherein a content of the filler is from 50 parts by mass or more and 500 parts by mass or less with respect to 100 parts by mass of the thermosetting resin.

[7] The thermosetting resin composition according to any one of [1] to [6] the thermosetting resin composition is a hole-filling material for a printed wiring board.

[8] A cured product, which is obtained by curing the thermosetting resin composition according to any one of [1] to [7].

[9] A printed wiring board comprising the cured product according to [8].

### Advantageous Effects of Invention

In the thermosetting resin composition according to the present invention, the semi-cured state and the fully cured state can be visually distinguished. In addition, the fully cured product of the thermosetting resin composition according to the present invention can be used for various purposes such as a hole-filling material and a printed wiring board using the same. Therefore, for example, when polishing the surface of the rivet portion of a through-hole in a printed wiring board to flatten the filled area, polishing conditions can be adjusted by visual judgment by applying the thermosetting resin composition according to the present invention, improving productivity.

### DETAILED DESCRIPTION OF THE INVENTION

Hereinafter, the thermosetting resin composition, cured product, and printed wiring board according to the present embodiment will be described.

### <Thermosetting Resin Composition>

The thermosetting resin composition according to the present invention is a thermosetting resin composition comprising a thermosetting resin, a curing agent, and a filler, wherein when
an L* value measured using an L*a*b* color system before curing the thermosetting resin composition is defined as L1,
an L* value measured using the L*a*b* color system for a semi-cured product obtained by thermally curing the thermosetting resin composition at 80° C. for 60 minutes is defined as L2, and
an L* value measured using the L*a*b* color system for a fully cured product obtained by further thermally curing the semi-cured product at 150° C. for 60 minutes is defined as L3, the thermosetting resin composition satisfies the following Formula 1:

$$( L 2 - L 3 ) / ( L 1 - L 3 ) \geq 0.7 . \qquad ( Formula 1 )$$

According to the present invention, (L2−L3)/(L1−L3)≥0.80 is preferable, and (L2−L3)/(L1−L3)≥0.90 is more preferable.

In addition, according to the present invention, (L2−L3)/(L1−L3)≤1.10 is preferable.

When the value of “(L2−L3)/(L1−L3)” satisfies the above-described numerical value, it is possible to visually distinguish between the semi-cured state and the fully cured state of the thermosetting resin composition. The L* value of the L*a*b* color system for the thermosetting resin composition is a value measured using a substrate that is manufactured according to the description in the Examples such that the film thickness of the thermosetting resin composition before curing is from 30 to 60 μm and a measurement method. It can be measured by a measurement method that allows the detection of diffuse reflection components using a commercially available spectroscopic side color meter, which is the SCE method (abbreviation for specular components exclude method, referred to as “diffuse reflection measurement method”) that removes specular reflection light for measurement. The method for adjusting the L* value of the thermosetting resin composition is not particularly limited. However, examples thereof include a method for appropriately adjusting the type and amount of a thermosetting resin, a method for appropriately adjusting the type and amount of a curing agent, a method for appropriately adjusting the filler type, particle size, and blending amount, and a method for appropriately adjusting the type and amount of a coloring agent, which will be described later for the thermosetting resin composition of the present invention.

From the viewpoint of heat resistance during electronic device mounting, the thermosetting resin composition according to the present invention preferably has a glass transition temperature (Tg) of 130° C. or more, more preferably 150° C. or more, particularly preferably 160° C. or more. The upper limit of the glass transition point (Tg) is not particularly limited; however, is preferably 200° C. or less.

The glass transition temperature of a thermosetting resin composition described herein is measured according to the following procedure.

On the glossy side (copper foil) of GTS-MP foil (manufactured by Furukawa Circuit Foil Co., Ltd.), a curable resin composition is printed using an applicator such that the coating film thickness before curing is from 100 to 150 μm. The printed copper foil is placed in a hot air circulation drying oven and held in a horizontal state at 150° C. for 1 hour, thereby completely curing the curable resin composition to obtain a cured coating film.

The obtained cured coating film is peeled off from the copper foil, and the cured coating film is cut out according to a measurement size (3 mm×10 mm size). The coefficient of thermal expansion (CTE) of the cured coating film is measured using TMA Q400EM manufactured by TA Instruments Japan Inc. For measurement conditions, by repeating twice heating the cured coating film from room temperature to 300° C. at a heating rate of 10° C./min with a test load of 5 g, the intersection of two different tangents of the linear expansion curve during the second temperature rise is defined as the glass transition temperature (Tg).

Hereinafter, the components contained in the thermosetting resin composition according to the present invention will be described.

### (Thermosetting Resin)

As a thermosetting resin, any resin that can be cured by heat can be used without particular limitations, but an epoxy resin can be preferably used. As an epoxy resin, any resin having two or more epoxy groups in one molecule can be used without any limitation. Examples thereof can include: epoxy resin having a bisphenol type skeleton described later, phenol novolac type epoxy resin described later, cresol novolak type epoxy resin, bisphenol A novolac type epoxy resin, biphenyl type epoxy resin, naphthol type epoxy resin, naphthalene type epoxy resin, dicyclopentadiene type epoxy resin, triphenylmethane type epoxy resin, alicyclic epoxy resin, aliphatic chain epoxy resin, phosphorus-containing epoxy resin, anthracene type epoxy resin, norbornene type epoxy resin, adamantane type epoxy resin, fluorene type epoxy resin, aminophenol type epoxy resin described later, aminocresol type epoxy resin, and alkylphenol type epoxy resin. The above-described epoxy resins may be used singly, or two or more types thereof may be used in combination.

Examples of an epoxy resin having a bisphenol type skeleton include bisphenol A type epoxy resin, bisphenol F type epoxy resin, bisphenol E (AD) type epoxy resin, and bisphenol S type epoxy resin. Among these, bisphenol A type epoxy resin, bisphenol F type epoxy resin, and bisphenol E (AD) type epoxy resin are preferable. In addition, the epoxy resin having a bisphenol type skeleton can be used in any of liquid, semi-solid, and solid forms, but the liquid form is particularly preferable from the viewpoint of filling properties. The term “liquid” refers to a liquid state that has fluidity at 20° C. or 45° C.

These epoxy resins having a bisphenol type skeleton may be used singly, or two or more types thereof may be used in combination, it is particularly preferable to use a combination of two types, bisphenol A type epoxy resin and bisphenol F type epoxy resin, or two types, bisphenol A type epoxy resin and bisphenol E type epoxy resin. Examples of commercially available products thereof include jER 828, jER 834, jER 1001 (bisphenol A type epoxy resin), jER 807, and jER 4004P (bisphenol F type epoxy resin) manufactured by Mitsubishi Chemical Corporation, and EPOX-MK R710 (bisphenol E type epoxy resin) manufactured by AIR WATER INC.

In addition, a polyfunctional epoxy resin may be contained as a thermosetting resin. Examples of a polyfunctional epoxy resin include: a hydroxybenzophenone type epoxy resin such as EP-3300E manufactured by ADEKA CORPORATION; aminophenol type epoxy resins (para-aminophenol epoxy resin) such as jER 630 manufactured by Mitsubishi Chemical Corporation and ELM-100 manufactured by SUMITOMO CHEMICAL COMPANY, LIMITED; glycidylamine type epoxy resins such as jER 604 manufactured by Mitsubishi Chemical Corporation, Epotote YH-434 manufactured by NIPPON STEEL Chemical & Material Co., Ltd., and SUMI-EPOXY (trademark) ELM-120 manufactured by SUMITOMO CHEMICAL COMPANY, LIMITED; and a phenol novolac type epoxy resin such as DEN-431 manufactured by The Dow Chemical Company. These polyfunctional epoxy resins may be used singly, or two or more types thereof may be used in combination.

### (Curing Agent)

As a curing agent for curing a thermosetting resin, any curing agent that is commonly used for curing thermosetting resins may be used as long as it has the effect of accelerating the curing reaction of thermosetting resins without particular limitations. Examples of the curing agent include amines, imidazoles, polyfunctional phenols, acid anhydrides, isocyanates, and polymers containing these functional groups, and a plurality of these may be used if necessary. Examples of amines include dicyandiamide and diaminodiphenylmethane. Examples of imidazoles include alkyl-substituted imidazole and benzimidazole. Further, imidazoles may be imidazole adducts and the like. Examples of polyfunctional phenols include hydroquinone, resorcinol, bisphenol A and its halogen compounds, as well as novolacs, which are condensates of these with aldehydes and resol resins. Examples of acid anhydrides include phthalic anhydride, hexahydrophthalic anhydride, methylnadic anhydride, and benzophenonetetracarboxylic acid. Examples of isocyanates include tolylene diisocyanate and isophorone diisocyanate, and these isocyanates may be masked with phenols and the like. These curing agents may be used singly, or two or more types thereof may be used in combination.

Among these, imidazoles are preferable. Imidazoles that are solid at room temperature are particularly preferable. Those having an activation temperature of more than 130° C. are more preferable because it becomes easier to visually distinguish between the semi-cured state and the fully cured state of the thermosetting resin composition. Further, sufficient curing under the curing conditions of 150° C. for 60 minutes is necessary. The activation temperature is preferably between more than 130° C. and 170° C., more preferably between more than 130° C. and 160° C., particularly preferably between more than 130° C. and 150° C. The activation temperature described herein refers to the peak top temperature when a sample (filler (composition)) is measured using a differential scanning calorimeter (DSC8500 manufactured by PerkinElmer Inc.) at a temperature increase of 5° C./min. Specific examples of imidazoles include 2-methylimidazole, 4-methyl-2-ethylimidazole, 2-phenylimidazole, 4-methyl-2-phenylimidazole, 1-benzyl-2-methylimidazole, 2-ethylimidazole, 2-isopropylimidazole, 1-cyanoethyl-2-methylimidazole, 1-cyanoethyl-2-ethyl-4-methylimidazole, 1-cyanoethyl-2-undecylimidazole, and 2-phenyl-4,5-dihydroxyimidazole. Specific examples of commercially available imidazoles include: imidazoles such as 2E4MZ, C11Z, C17Z, and 2PZ (trade names); imidazole azine compounds such as 2MZ-A and 2E4MZ-A (trade names); isocyanurates of imidazole such as 2MZ-OK and 2PZ-OK (trade names); and imidazoles in the hydroxymethyl form such as 2PHZ and 2P4 MHZ (trade names) (all of these are manufactured by SHIKOKU CHEMICALS CORPORATION). Among these, specific examples of imidazoles having activation temperatures within the above-described preferable range include 2,4-diamino-6-(2′-methylimidazolyl(1′))-ethyl-s-triazine, 2,4-diamino-6-(2′-ethyl-4′-methylimidazolyl(1′))-ethyl-s-triazine, 2-phenyl-4,5-dihydroxymethylimidazole, and 2-phenyl-4-methyl-5-hydroxylmethylimidazole. In addition, examples of preferable commercially available products include 2MZ-A which is an azinide of 2MZ, 2E4MZ-A which is an azinide of 2E4MZ, 2PHZ and 2P4 MHZ which are methoxyphenolized 2MZs (all of these are manufactured by SHIKOKU CHEMICALS CORPORATION).

The content of the curing agent in the thermosetting resin composition is preferably from 3 parts by mass or more and 20 parts by mass or less, more preferably from 5 parts by mass or more and 15 parts by mass or less, particularly preferably from 5 parts by mass or more and 10 parts by mass or less with respect to 100 parts by mass of the thermosetting resin. When the content of the curing agent in the thermosetting resin composition is within the numerical range described above, it is preferable because the initial curing rate of the thermosetting resin is suitable, and the occurrence of voids and cracks in the cured product can be suppressed, and thus, it becomes easier to visually distinguish between the semi-cured state and the fully cured state of the thermosetting resin composition.

### (Filler)

As the filler contained in the thermosetting resin composition, inorganic fillers such as silica, metal oxides, metal carbonates, metal sulfates, and metal sulfides can be used. Among these inorganic fillers, silica, metal carbonates, and metal sulfates are preferable. Preferable metals for metal carbonates and metal sulfates are alkaline earth metals such as magnesium, calcium, and barium. For example, calcium carbonate, magnesium carbonate, and the like can be used as metal carbonates. In addition, for example, barium sulfate and the like can be used as metal sulfates. These fillers may be used singly, or two or more types thereof may be used in combination.

The average particle size of the filler is usually from 0.1 to 25 μm, preferably from 0.5 to 10 μm, more preferably from 1 to 10 μm. The shape of the filler may be spherical, acicular, plate-like, scale-like, hollow, amorphous, hexagonal, cubic, flaky, or the like; however, it is preferably spherical from the viewpoint of high filling properties.

The content of the filler is preferably from 50 parts by mass or more and 500 parts by mass or less, more preferably from 70 parts by mass or more and 400 parts by mass or less, still more preferably from 100 parts by mass or more and 350 parts by mass or less, even still more preferably from 110 parts by mass or more and 300 parts by mass or less with respect to a total of 100 parts by mass of the thermosetting resin and the curing agent. When the content of the filler in the thermosetting resin composition is within the numerical range described above, it is preferable because the cured product can exhibit sufficiently low volume expansion and have favorable polishability.

### (Photocurable Resin)

The thermosetting resin composition according to the present invention may contain a photocurable resin in combination with the above-described thermosetting resin. Examples of a photocurable resin include curable resins that can be cured by a radical addition polymerization reaction with active energy rays. Specific examples of a radical-addition-polymerization reactive component having one or more ethylenically unsaturated groups in its molecule include publicly known polyester (meth)acrylate, polyether (meth)acrylate, urethane (meth)acrylate, carbonate (meth)acrylate, and epoxy (meth)acrylate. Specific examples thereof include, but are not limited to, glycol diacrylates such as ethylene glycol, methoxytetraethylene glycol, polyethylene glycol, and propylene glycol; acrylamides such as N,N-dimethylacrylamide, N-methylolacrylamide, and N,N-dimethylaminopropylacrylamide; aminoalkyl acrylates such as N, N-dimethylaminoethyl acrylate and N,N-dimethylaminopropyl acrylate; polyvalent acrylates of polyhydric alcohols such as hexanediol, trimethylolpropane, pentaerythritol, dipentaerythritol, and tris-hydroxyethyl isocyanurate, or ethylene oxide adducts, propylene oxide adducts, or ε-caprolactone adducts of these polyhydric alcohols; polyvalent acrylates such as phenoxy acrylate, bisphenol A diacrylate, and ethylene oxide adducts or propylene oxide adducts of these phenols; and polyvalent acrylates of glycidyl ether such as glycerin diglycidyl ether, glycerin triglycidyl ether, trimethylolpropane triglycidyl ether, and triglycidyl isocyanurate; as well as acrylates obtained by directly converting polyols, such as polyether polyol, polycarbonate diol, hydroxyl-terminated polybutadiene, and polyester polyol, into acrylates or converting the polyols into urethane acrylates via diisocyanate, melamine acrylate, and at least any one of methacrylates corresponding to the above-described acrylates. Note that “(meth)acrylate” described herein is a term that collectively refers to acrylate, methacrylate, and a mixture thereof, and the same applies to other similar expressions. The photocurable resin described above is preferably in the liquid form.

Further, in the case of accelerating a thermosetting reaction with an epoxy resin in the thermosetting resin composition according to the present invention or obtaining the thermosetting resin composition according to the present invention as an alkali-developable thermosetting resin composition, it is preferable to use a carboxyl group-containing resin as the curable resin. The carboxyl group-containing resin may be a carboxyl group-containing photosensitive resin having an ethylenically unsaturated group, and may or may not have an aromatic ring.

In a case in which a photocurable resin is contained in the thermosetting resin composition according to the present invention, it is preferable to add a photoinitiator. Examples of such a photoinitiator include benzoin compounds and their alkyl ethers such as benzoin, benzoin methyl ether, benzoin ethyl ether, benzoin isopropyl ether, benzoin isobutyl ether, and benzyl methyl ketal; acetophenones such as acetophenone, 2,2-dimethoxy-2-phenylacetophenone, 2-hydroxy-2-methyl-1-phenylpropan-1-one, diethoxyacetophenone, 2,2-diethoxy-2-phenylacetophenone, 1,1-dichloroacetophenone, 1-hydroxycyclohexylphenylketone, and 2-methyl-1-[4-(methylthio)phenyl]-2-morpholino-propan-1-one; anthraquinones such as methylanthraquinone, 2-ethylanthraquinone, 2-tert-butylanthraquinone, 1-chloroanthraquinone, and 2-amylanthraquinone; thioxanthones such as thioxanthone, 2,4-diethylthioxanthone, 2-chlorothioxanthone, 2,4-dichlorothioxanthone, 2-methylthioxanthone, and 2,4-diisopropylthioxanthone; ketals such as acetophenone dimethyl ketal and benzyl dimethyl ketal; and benzophenones such as benzophenone and 4,4-bismethylaminobenzophenone. These can be used singly or in combination of two or more. Furthermore, the photoinitiator can be used in combination with photoinitiator aids, including tertiary amines such as triethanolamine and methyldiethanolamine, benzoic acid derivatives such as 2-dimethylaminoethylbenzoic acid and ethyl 4-dimethylaminobenzoate, and the like.

In addition, the thermosetting resin composition according to the present invention may comprise a silane coupling agent. By blending a silane coupling agent, it is possible to improve the adhesion between the above-described filler and thermosetting resin, and to suppress the occurrence of cracks in the cured product.

The thermosetting resin composition according to the present invention may be blended with an oxazine compound with an oxazine ring obtained by reacting a phenol compound, formalin, and a primary amine, in addition to the above, if necessary. As the thermosetting resin composition contains an oxazine compound, when the thermosetting resin composition filled in the holes of a printed wiring board is cured and then electroless plating is performed on the cured product, it is possible to facilitate roughening of the cured product using a potassium permanganate aqueous solution or the like and improve peel strength of the plate.

In addition, a conventionally known coloring agent such as a red, blue, green, or yellow coloring agent can be added to the thermosetting resin composition according to the present invention as long as the properties thereof are not impaired. Any pigment, dye, or color matter may be added. Examples thereof include known coloring agents such as phthalocyanine blue, phthalocyanine green, disazo yellow, carbon black, and naphthalene black.

Further, it is possible to add known thermal polymerization inhibitors such as hydroquinone, hydroquinone monomethyl ether, tert-butylcatechol, pyrogallol, and phenothiazine for providing storage stability during storage and known thickeners and thixotropic agents such as clay, kaolin, organic bentonite, and montmorillonite for adjusting viscosity and the like. In addition, known additives such as silicone-based, fluorine-based, and polymer-based antifoaming agents, leveling agents, and adhesion improvers such as imidazole-based, thiazole-based, and triazole-based silane coupling agents can be blended. In particular, when organic bentonite is used, it is preferable because the portion protruding from the hole surface is easily formed in a protruding state that is easy to polish and remove, resulting in excellent polishability.

The thermosetting resin composition according to the present invention preferably has a viscosity of from 5 to 250 Pa·s, more preferably from 7 to 200 Pa·s, still more preferably from 10 to 150 Pa·s in consideration of coatability (printability). The viscosity of the thermosetting resin composition can be adjusted depending on the amount of diluent components whose 5% weight loss temperature as determined by thermogravimetric analysis is from 50° C. to 180° C., types and amounts of components of thermosetting resins whose 5% weight loss temperature exceeds 180° C. by thermogravimetric analysis, and the like.

### <Intended Use of Thermosetting Resin Composition>

The thermosetting resin composition according to the present invention can be used widely and generally. However, it is preferably used for forming a cured film of a printed wiring board, more preferably for forming a permanent protective film, still more preferably for being used as a solder resist, an interlayer insulating layer, a coverlay, or a hole-filling material. Among these intended uses, it is particularly preferable to use it as a hole-filling material specifically for filling through-holes such as through-holes and recesses in a printed wiring board.

In a case in which the thermosetting resin composition according to the present invention is used as a hole-filling material, the filler can be filled in a hole of a through-hole or a recess having a bottom in a multilayer printed wiring board using a known patterning method such as screen printing, roll coating, die coating, or vacuum printing. Preferably, the hole filled with the thermosetting resin composition has an inner diameter of from 0.05 to 0.8 mm and a depth of from 0.4 to 10 mm. Preferably, the recess filled with the thermosetting resin composition has an inner diameter of 0.1 mm or more and a depth of 0.8 mm or less. At such time, it is preferable to completely fill the thermosetting resin composition such that it slightly protrudes from the hole or recess.

A multilayer printed wiring board with holes and recesses filled with a liquid thermosetting resin composition is heated at, for example, from 80° C. to 160° C. for about 30 to 180 minutes such that the thermosetting resin composition is cured, thereby forming a cured product. From the viewpoint of easily removing unnecessary portions of the cured product that protrude from the substrate surface after filling the holes by physical polishing, it is preferable that the thermosetting resin composition is cured in two stages. In other words, the thermosetting resin composition can be semi-cured at a lower temperature and then fully cured (finishing curing). The conditions for semi-curing are preferably heating from 80° C. to 110° C. for about 30 to 180 minutes. Since the hardness of the semi-cured product is relatively low, unnecessary portions protruding from the substrate surface can be easily removed by physical polishing, and a flat surface can be obtained. Thereafter, the semi-cured product is heated to be fully cured. The conditions for full curing are preferably heating from 130° C. to 180° C. for 30 to 180 minutes. Physical polishing of unnecessary portions protruding from the substrate surface can also be performed after full curing.

Curing can be carried out using a hot air circulation drying oven, an IR oven, a hot plate, a convection oven, or the like (by a method for bringing the hot air inside the drying oven into countercurrent contact using a device equipped with an air heating type heat source using steam and a method for blowing the hot air from a nozzle onto an object to be cured) both in semi-curing and full curing. Among these, a hot air circulation drying oven is particularly preferable. At such time, due to the low expansion property, the cured product hardly expands or contracts, resulting in a final cured product having favorable dimensional stability and excellent low hygroscopicity, adhesion, electrical insulation, and the like. The hardness of the semi-cured product can be controlled by changing the heating time and heating temperature for semi-curing.

In the present invention, the thermosetting resin composition may be cured by irradiating active energy rays, if necessary. In a case in which the thermosetting resin composition contains a photocurable resin such as a carboxyl group-containing photosensitive resin, for example, by performing exposure (light irradiation) using an ultraviolet exposure machine equipped with a high-pressure mercury lamp or a metal halide lamp at a cumulative light intensity of about 500 to 2000 mJ/cm², the exposed portion (light-irradiated portion) is cured. Further, for example, curing (post-curing) can be performed by heating to a temperature of about 100° C. to 180° C.

After the thermosetting resin composition is cured as described above, unnecessary parts of the cured product protruding from the surface of the printed wiring board are removed and flattened using a known physical polishing method. Then, the surface wiring layer is patterned into a predetermined pattern. Thus, a predetermined circuit pattern is formed. After roughening the surface of the cured product using an aqueous potassium permanganate solution or the like, if necessary, a wiring layer may be formed on the cured product by electroless plating or the like.

### <Cured Product>

The cured product according to the present invention is obtained by curing the thermosetting resin composition according to the present invention. The cured product according to the present invention can be suitably used in a hole-filling material for a printed wiring board.

### <Printed Wiring Board>

The printed wiring board according to the present invention comprises the cured product according to the present invention. The printed wiring board according to the present invention is preferably a multilayer printed wiring board in which through-holes or the like are filled with the cured product.

Examples of an insulating layer that constitutes the printed wiring board can include paper phenol, paper epoxy, glass cloth epoxy, glass polyimide, glass cloth/nonwoven epoxy, glass cloth/paper epoxy, synthetic fiber epoxy, fluororesin, polyphenylene ether, polyphenylene oxide, cyanate ester, polyimide film, polyethylene terephthalate film, polyethylene naphthalate (PEN) film, glass, ceramic, and silicon wafer.

### Examples

Next, the present invention will be explained in more detail with reference to Examples; however, the present invention is not limited to these Examples. In addition, “part(s)” and “%” below are each based on mass unless otherwise specified.

### <Synthesis of Fluororesin>

### (Synthesis Example)

A fluororesin (copolymer of tetrafluoroethylene and vinyl acetate (monomer ratio of tetrafluoroethylene and vinyl acetate=1/1)) was prepared by a known method, thereby obtaining a fluororesin having a hydroxyl value of 60 mg/g (KOH).

### <Preparation of Thermosetting Resin Composition>

The various components shown in Table 1 below were blended in the proportions (parts by mass) shown in Table 1, premixed, and then dispersed and mixed in a three-roll mill. Thus, thermosetting resin compositions of Examples 1 to 4 and Comparative Examples 1 and 2 were obtained.

TABLE 1

| | | | | | Co. | Co. |
|---|---|---|---|---|---|---|
| | Ex. 1 | Ex. 2 | Ex. 3 | Ex. 4 | Ex. 1 | Ex. 2 |
| Resin | | | | | | |
| *1 Bisphenol E type epoxy | 93.7 | 0 | 35 | 0 | 20 | 0 |
| resin | | | | | | |
| *2 Bisphenol A type epoxy | 0 | 0 | 25 | 0 | 30 | 0 |
| resin | | | | | | |
| *3 Bisphenol A type epoxy | 0 | 44.4 | 0 | 44.4 | 0 | 0 |
| resin | | | | | | |
| *4 Bisphenol F type epoxy | 0 | 22.2 | 0 | 22.2 | 0 | 0 |
| resin | | | | | | |
| *5 Glycidylamine type | 0 | 0 | 42.5 | 0 | 31 | 0 |
| epoxy resin | | | | | | |
| *6 Aminophenol type | 0 | 33.3 | 0 | 33.3 | 0 | 0 |
| epoxy resin | | | | | | |
| *7 Fluororesin | 0 | 0 | 0 | 0 | 0 | 40 |
| *8 Isocyanate | 0 | 0 | 0 | 0 | 0 | 3.1 |
| Curing agent | | | | | | |
| *9 Imidazole type epoxy | 6.6 | 6.7 | 8 | 6.7 | 6 | 0 |
| curing agent | | | | | | |
| *10 Polyamine epoxy | 0 | 0 | 0 | 0 | 6 | 0 |
| curing agent | | | | | | |
| Filler | | | | | | |
| *11 Barium sulfate | 8 | 0 | 0 | 0 | 0 | 0 |
| *12 Spherical silica | 133 | 0 | 0 | 0 | 0 | 0 |
| *13 Spherical silica | 0 | 0 | 240 | 0 | 0 | 0 |
| *14 Calcium carbonate | 20 | 120 | 40 | 120 | 130 | 0 |
| *15 Titanium oxide | 0 | 0 | 0 | 0 | 0 | 59.4 |
| *16 Fine powder silica | 0 | 0 | 0 | 0 | 0 | 7 |
| *17 Pigment | 0 | 0 | 0 | 5 | 0 | 0 |

Note that *1 to *17 in Table 1 represent the following components, respectively.
*1: Bisphenol E type epoxy resin (EPOX- MK R710 manufactured by AIR WATER INC.)
*2: Bisphenol A type epoxy resin (jER 828 manufactured by Mitsubishi Chemical Corporation)
*3: Bisphenol A type epoxy resin (EPICLON 840-S manufactured by DIC Corporation)
*4: Bisphenol F type epoxy resin (RE-304S manufactured by Nippon Kayaku Co., Ltd.)
*5: Aminophenol type epoxy resin (jER 630 manufactured by Mitsubishi Chemical Corporation)
*6: Glycidylamine type epoxy resin (jER 604 manufactured by Mitsubishi Chemical Corporation)
*7: Fluororesin prepared in Synthesis Example
*8: Isocyanate (Desmodur (registered trademark) BI-3175 manufactured by Sumitomo Bayer Urethane Co., Ltd.)
*9: Imidazole type curing agent (activation temperature: from more than 130° C. to 150° C.; 2MZA manufactured by SHIKOKU CHEMICALS CORPORATION)
*10: Polyamine epoxy curing agent (Fujicur FXR-1020 manufactured by T&K TOKA CO., LTD.)
*11: Barium sulfate (BARIACE B-33 manufactured by SAKAI CHEMICAL INDUSTRY CO., LTD.)
*12: Spherical silica (MSS-6 manufactured by TATSUMORI LTD.)
*13: Spherical silica (MSS-7 manufactured by TATSUMORI LTD.)
*14: Calcium carbonate (Softon 1500 manufactured by SHIRAISHI CALCIUM KAISHA, LTD.)
*15: Titanium oxide (TIPAQUE (registered trademark) CR-93 manufactured by ISHIHARA SANGYO KAISHA, LTD.)
*16: Fine powder silica (Nipsil (registered trademark) E-743 manufactured by TOSOH SILICA CORPORATION)
*17: Green pigment

### <Preparation of Test Substrate>

The surface of a 1.2-mm thick glass substrate (made of soda glass; length: 160 mm; width: 110 mm) was degreased with alcohol. Subsequently, the thermosetting resin compositions of Examples 1 to 4 and Comparative Examples 1 to 2 in Table 1 above were each applied to the surface of a glass substrate using an applicator such that the film thickness before curing was 50 μm. These substrates were thermally cured at 80° C. for 60 minutes using a hot air circulation drying oven (trade name: DF610 manufactured by Yamato Scientific Co., Ltd.), thereby obtaining a semi-cured substrate. Then, the semi-cured substrate was thermally cured at 150° C. for 60 minutes, thereby obtaining a substrate after full curing.

### <Measurement of L* Value>

The L* values of the test substrates produced in the test substrate production above were measured using reflected light using a spectrophotometric colorimeter (CM-5, manufactured by KONICA MINOLTA, INC.).

### Measurement Conditions:

### Software: CM-S100w “SpectraMagic NX”

Reflection measurement: SCE
Measurement diameter: ϕ 8 mm

Zero calibration was performed by covering each test substrate with the supplied zero calibration box CM-A124. Then, white calibration was performed using the built-in white calibration plate. Subsequently, the L* value of the L*a*b* color system was measured with the substrate before curing, after semi-curing, and after full curing with the glass surface facing down. The measurement results are shown in Table 2. The measurement results are the average values of three measurements.

### <Determination by Visual Observation>

The thermosetting resin compositions of Examples 1 to 4 and Comparative Examples 1 to 2 were each filled into the through-holes of a patterned multilayer printed wiring board by screen printing. A substrate after semi-curing and a substrate after full curing were prepared under the same conditions as <Preparation of Test Substrate> and placed side by side on a rack, with each substrate placed at an angle of 90 degrees±10 degrees with respect to the placement surface. The following criteria were used to evaluate whether the discoloration degree could be visually distinguished. The evaluation results are shown in Table 2.

### [Evaluation Criteria]

⊚: The thermosetting resin composition after semi-curing and the thermosetting resin composition after full curing could be easily distinguished by visual observation.

∘; The thermosetting resin composition after semi-curing and the thermosetting resin composition after full curing could be distinguished by visual observation.

x: The thermosetting resin composition after semi-curing and the thermosetting resin composition after full curing could not be distinguished by visual observation.

### <Measurement of Glass Transition Point (Tg)>

The glass transition points (Tg) of the curable resin compositions of the Examples were measured according to the following procedure.

On the glossy side (copper foil) of GTS-MP foil (manufactured by Furukawa Circuit Foil Co., Ltd.), each of the curable resin compositions of the Examples was printed using an applicator such that the coating film thickness before curing was from 100 to 150 μm. The printed copper foil was placed in a hot air circulation drying oven and held in a horizontal state at 150° C. for 1 hour, thereby completely curing each curable resin composition to obtain each cured coating film.

Each of the obtained cured coating films was peeled off from the copper foil, and each cured coating film was cut out according to a measurement size (3 mm×10 mm size). The coefficient of thermal expansion (CTE) of each cured coating film was measured using TMA Q400EM manufactured by TA Instruments Japan Inc. For measurement conditions, by repeating twice heating each cured coating film from room temperature to 300° C. at a heating rate of 10° C./min with a test load of 5 g, the intersection of two different tangents of the linear expansion curve during the second temperature rise was defined as the glass transition temperature (Tg). Table 2 shows the glass transition points (Tg) of the curable resin compositions of the Examples.

TABLE 2

| | | | | | Co. | Co. |
|---|---|---|---|---|---|---|
| | Ex. 1 | Ex. 2 | Ex. 3 | Ex. 4 | Ex. 1 | Ex. 2 |
| L* value before | 55.40 | 59.61 | 63.95 | 50.08 | 47.72 | 84.46 |
| curing (L1) | | | | | | |
| L* value after | 55.55 | 58.21 | 63.83 | 49.44 | 46.52 | 84.06 |
| semi-curing (L2) | | | | | | |
| L* value after full | 45.98 | 53.41 | 47.54 | 37.23 | 45.60 | 83.94 |
| curing (L3) | | | | | | |
| L2 − L3 | 9.57 | 4.80 | 16.29 | 12.21 | 0.92 | 0.12 |
| L1 − L3 | 9.42 | 6.20 | 16.41 | 12.85 | 2.12 | 0.52 |
| (L2 − L3)/(L1 − | 1.02 | 0.77 | 0.99 | 0.95 | 0.43 | 0.23 |
| L3)^{※} | | | | | | |
| Determination by | ⊚ | ◯ | ⊚ | ⊚ | X | X |
| visual observation | | | | | | |
| Glass transition | 150 | 160 | 165 | 160 | — | — |
| point (Tg) (° C.) | | | | | | |

*Calculated values are values rounded to the third decimal place.

1. A thermosetting resin composition comprising a thermosetting resin, a curing agent, and a filler, wherein when
an L* value measured using an L*a*b* color system before curing the thermosetting resin composition is defined as L1,
an L* value measured using the L*a*b* color system for a semi-cured product obtained by thermally curing the thermosetting resin composition at 80° C. for 60 minutes is defined as L2, and
an L* value measured using the L*a*b* color system for a fully cured product obtained by further thermally curing the semi-cured product at 150° C. for 60 minutes is defined as L3,
the thermosetting resin composition satisfies the following Formula 1:
$$( L 2 - L 3 ) / ( L 1 - L 3 ) \geq 0.7 . \qquad ( Formula 1 )$$

2. The thermosetting resin composition according to claim 1, wherein L1, L2, and L3 satisfy the following Formula 2:
$$( L 2 - L 3 ) / ( L 1 - L 3 ) \geq 0.9 . \qquad ( Formula 2 )$$

3. The thermosetting resin composition according to claim 1, wherein the thermosetting resin is an epoxy resin.

4. The thermosetting resin composition according to claim 1, wherein the curing agent is an imidazole.

5. The thermosetting resin composition according to claim 1, wherein a content of the curing agent is from 3 parts by mass or more and 20 parts by mass or less with respect to 100 parts by mass of the thermosetting resin.

6. The thermosetting resin composition according to claim 1, wherein a content of the filler is from 50 parts by mass or more and 500 parts by mass or less with respect to 100 parts by mass of the thermosetting resin.

7. The thermosetting resin composition according to claim 1, wherein the thermosetting resin composition is a hole-filling material for a printed wiring board.

8. A cured product, which is obtained by curing the thermosetting resin composition according to claim 1.

9. A printed wiring board comprising the cured product according to claim 8.
